(19) United States
(12) Patent Application Publication
(10) Pub. No.: US 2024/0105844 A1
(43) Pub. Date: Mar. 28, 2024

(54) NATIVE NMOS DEVICE AND MANUFACTURING METHOD THEREOF

(71) Applicant: Richtek Technology Corporation, Zhubei City (TW)

(72) Inventors: Ying-Shiou Lin, Chiayi (TW); Wu-Te Weng, Hsinchu (TW); Yong-Zhong Hu, Hsinchu (TW)

(21) Appl. No.: 18/462,803

(22) Filed: Sep. 7, 2023

(30) Foreign Application Priority Data
Sep. 26, 2022 (TW) 111136429

(51) Int. Cl. H01L 29/78; H01L 29/66

(52) U.S. Cl. CPC H01L 29/7833; H01L 29/66492

(57) ABSTRACT

A native NMOS device includes: a P-type epitaxial layer, a first and a second insulation region, a first P-type well, a second P-type well, a gate, an N-type source, and an N-type drain. The P-type epitaxial layer has a first concentration of P-type doped impurities. The first P-type well completely encompasses and is in contact with a lower surface of the N-type source. The second P-type well completely encompasses and is in contact with a lower surface of the N-type drain. Each of the first P-type well and the second P-type well has a second concentration of P-type doped impurities, and the second concentration of P-type doped impurities is higher than the first concentration of P-type doped impurities. The second concentration of P-type doped impurities is sufficient for preventing a leakage current from flowing between the N-type drain and the P-type substrate while the native NMOS device is in operation.

### CROSS REFERENCE

The present invention claims priority to TW 111136429 filed on Sep. 26, 2022.

### BACKGROUND OF THE INVENTION

### Field of Invention

The present invention relates to a native NMOS device and a manufacturing method thereof; particularly, it relates to such native NMOS device capable of avoiding leakage current and a manufacturing method of such native NMOS device.

### Description of Related Art

FIG. 1 shows a cross-section view of a conventional native NMOS device. The conventional native NMOS device 10 comprises: a P-type epitaxial layer 111, insulation regions 121 and 122, a gate 13, an N-type source 14, an N-type drain 15 and a P-type contact pole 112. The P-type epitaxial layer 111 is formed on a P-type substrate 11. The N-type source 14 and the N-type drain 15 are located below and outside two sides of the gate 13, respectively, wherein the side of the gate 13 which is closer to the N-type source 14 is a source side and the side of the gate 13 which is closer to the N-type drain 15 is a drain side. The gate 13 includes: a conductive layer, a spacer layer and a dielectric layer, which is well known to a person having ordinary skill in the art, so the details thereof are not redundantly explained here.

US Patent Publication No. 2014/0197497 A1 discloses a native NMOS device and manufacturing method thereof. The native NMOS device of this prior art has a low threshold voltage and a high driving current. Still another prior art, EU Patent Publication No. EP0902466 A1 discloses a manufacturing method of a native NMOS device. The manufacturing method of the native NMOS device of this prior art integrates the process steps for manufacturing the native NMS device with the process steps for manufacturing a non-volatile memory (NVM).

The prior art native NMOS device shown in FIG. 1 and the native NMOS devices disclosed in the other two prior arts mentioned above all have a drawback of high leakage current. That is, either when the native NMOS device is ON or the native NMOS device is OFF, there are leakage current and punch through leakage, which leads to limitation of the application scope of the device. Besides, the manufacturing costs of the prior art native NMOS devices are high and the prior art native NMOS devices have restrictions in device size shrinkage.

In view of the above, to overcome the drawbacks in the prior art, the present invention proposes a native NMOS device capable of avoiding leakage current and a manufacturing method thereof, whereby the application scope is broadened and manufacturing cost is reduced. Besides, under the same specification for leakage current and punch through leakage, as compared to the prior art devices, the native NMOS device of the present invention has a relatively smaller size.

### SUMMARY OF THE INVENTION

From one perspective, the present invention provides a native NMOS device, comprising: a P-type epitaxial layer, which is formed on a P-type substrate, wherein the P-type epitaxial layer has a first concentration of P-type doped impurities; a first insulation region and a second insulation region, both of which are formed on the P-type epitaxial layer, wherein the first insulation region and the second insulation region are configured to define an operation region between the first insulation region and the second insulation region; a first P-type well and a second P-type well, both of which are formed in the P-type epitaxial layer by one same ion implantation process step; a gate, which is formed on the P-type epitaxial layer within the operation region; and an N-type source and an N-type drain, both of which are formed in the P-type epitaxial layer within the operation region by one same ion implantation process step, wherein the N-type source and the N-type drain are located below and outside two sides of the gate, respectively, wherein the side of the gate which is closer to the N-type source is a source side and the side of the gate which is closer to the N-type drain is a drain side, and wherein the N-type source is located on the first P-type well, and the N-type drain is located on the second P-type well; wherein the first P-type well completely encompasses and is in contact with a lower surface of the N-type source; wherein the second P-type well completely encompasses and is in contact with a lower surface of the N-type drain; wherein each of the first P-type well and the second P-type well has a second concentration of P-type doped impurities, and wherein the second concentration of P-type doped impurities is higher than the first concentration of P-type doped impurities; wherein the second concentration of P-type doped impurities is sufficient for preventing a leakage current from flowing between the N-type drain and the P-type substrate while the native NMOS device is in operation.

From another perspective, the present invention provides a manufacturing method of a native NMOS device, comprising following steps: forming a P-type epitaxial layer on a P-type substrate, wherein the P-type epitaxial layer has a first concentration of P-type doped impurities; forming a first insulation region and a second insulation region on the P-type epitaxial layer, wherein the first insulation region and the second insulation region are configured to define an operation region between the first insulation region and the second insulation region; forming a first P-type well and a second P-type well in the P-type epitaxial layer by one same ion implantation process step; forming a gate on the P-type epitaxial layer within the operation region; and forming an N-type source and an N-type drain in the P-type epitaxial layer within the operation region by one same ion implantation process step, wherein the N-type source and the N-type drain are located below and outside two sides of the gate, respectively, wherein the side of the gate which is closer to the N-type source is a source side and the side of the gate which is closer to the N-type drain is a drain side, and wherein the N-type source is located on the first P-type well, and the N-type drain is located on the second P-type well; wherein the first P-type well completely encompasses and is in contact with a lower surface of the N-type source; wherein the second P-type well completely encompasses and is in contact with a lower surface of the N-type drain; wherein each of the first P-type well and the second P-type well has a second concentration of P-type doped impurities, and wherein the second concentration of P-type doped impurities is higher than the first concentration of P-type doped impurities; wherein the second concentration of P-type doped impurities is sufficient for preventing a leakage current from flowing between the N-type drain and the P-type substrate while the native NMOS device is in operation.

In one embodiment, the native NMOS device further comprises: a first pocket region and a second pocket region, both of which are located vertically below the gate and are formed in the P-type epitaxial layer outside the first P-type well and the second P-type well, respectively, by one same ion implantation process step; wherein each of the first pocket region and the second pocket region has a third concentration of P-type doped impurities, and wherein the third concentration of P-type doped impurities is higher than the first concentration of P-type doped impurities; wherein the third concentration of P-type doped impurities is sufficient for preventing the leakage current from flowing between the N-type drain and the N-type source while the native NMOS device is OFF.

In one embodiment, the native NMOS device further comprises: a first N-type lightly doped drain (LDD) and a second N-type LDD, both of which are located vertically below the gate and are formed in the P-type epitaxial layer outside the N-type source and the N-type drain, respectively, by one same ion implantation process step; wherein the first N-type LDD and the second N-type LDD are in contact with outside of the N-type source and the N-type drain, respectively, wherein the outsides of the N-type source and the N-type drain are in the P-type epitaxial layer which is located vertically below the gate.

In one embodiment, within the operation region, there is no other N-type region in the P-type epitaxial layer, except the N-type source and the N-type drain.

In one embodiment, within the operation region, there is no other N-type region in the P-type epitaxial layer, except the N-type source, the N-type drain, the first N-type LDD and the second N-type LDD.

In one embodiment, the native NMOS device further comprises: an N-type buried layer, which is formed below and in contact with the P-type epitaxial layer, wherein the N-type buried layer completely encompasses the P-type epitaxial layer within the operation region; and a first isolation region and a second isolation region, both of which are located on the N-type buried layer and are formed in the P-type epitaxial layer outside the first insulation region and the second insulation region, respectively, by one same ion implantation process step; wherein both the first isolation region and the second isolation region are not within the operation region.

In one embodiment wherein the native NMOS device includes the first N-type LDD and the second N-type LDD, within the operation region, there is no other N-type region in the P-type epitaxial layer, except the N-type source, the N-type drain, the first N-type LDD, the second N-type LDD and the N-type buried layer; and in another embodiment wherein the native NMOS device does not include the first N-type LDD and the second N-type LDD, within the operation region, there is no other N-type region in the P-type epitaxial layer, except the N-type source, the N-type drain and the N-type buried layer.

In one embodiment, the P-type epitaxial layer has a volume resistance which is equal to 45 Ohm-cm.

The present invention is advantageous over prior art devices in that, among other things, in the native NMOS device and manufacturing method of the native NMOS device of the present invention, a leakage current is avoided in ON and OFF operations of the native NMOS device.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-section view of a conventional native NMOS device.

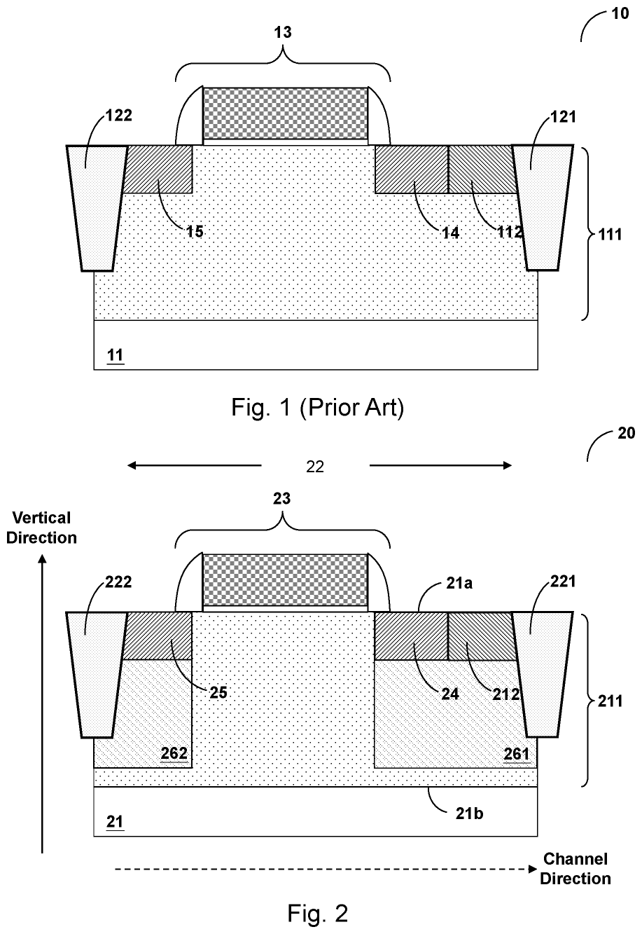

FIG. 2 shows a cross-section view of a native NMOS device according to an embodiment of the present invention.

FIG. 3 shows a cross-section view of a native NMOS device according to an embodiment of the present invention.

FIG. 4 shows a cross-section view of a native NMOS device according to an embodiment of the present invention.

FIG. 5 shows a cross-section view of a native NMOS device according to an embodiment of the present invention.

FIG. 6 shows a cross-section view of a native NMOS device according to an embodiment of the present invention.

FIG. 7 shows a cross-section view of a native NMOS device according to an embodiment of the present invention.

FIG. 8 shows a cross-section view of a native NMOS device according to an embodiment of the present invention.

FIG. 9 shows a cross-section view of a native NMOS device according to an embodiment of the present invention.

FIG. 10A to FIG. 10K show cross-section views of a manufacturing method of a native NMOS device according to an embodiment of the present invention.

### DESCRIPTION OF THE PREFERRED EMBODIMENTS

The drawings as referred to throughout the description of the present invention are for illustration only, to show the interrelations among the process steps and the layers, but the shapes, thicknesses, and widths are not drawn in actual scale.

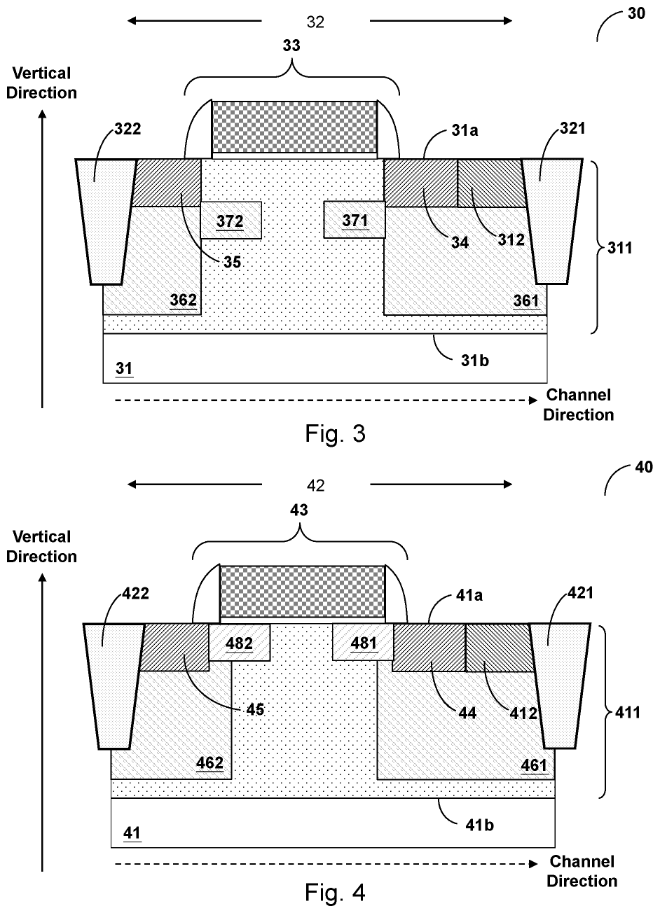

Please refer to FIG. 2, which shows a cross-section view of a native NMOS device 20 according to an embodiment of the present invention. As shown in FIG. 2, the native NMOS device 20 comprises: a P-type epitaxial layer 211, a first insulation region 221, a second insulation region 222, a gate 23, an N-type source 24, an N-type drain 25, a first P-type well 261, a second P-type well 262 and a P-type contact pole 212.

The P-type epitaxial layer 211 is formed on a P-type substrate 21 and has a P-type conductivity, wherein the P-type epitaxial layer 211 has a first concentration of P-type doped impurities. The P-type epitaxial layer 211 has a top surface 21a and a bottom surface 21b that is opposite to the top surface 21a in the vertical direction (as indicated by the direction of the solid arrow in FIG. 2, and all occurrences of the term “vertical direction” in this specification refer to the same direction). The P-type substrate 21 is, for example but not limited to, a P-conductivity type or an N-conductivity type semiconductor substrate. The P-type epitaxial layer 211, for example, is formed on the P-type substrate 21 by an epitaxial growth process step. A part of the P-type epitaxial layer 211 serves to provide a conduction current channel when the native NMOS device 20 operates in the ON operation.

Please still refer to FIG. 2. The first insulation region 221 and the second insulation region 222 are formed on the P-type epitaxial layer 211, wherein the first insulation region 221 and the second insulation region 222 are configured to define an operation region 22 between the first insulation region 221 and the second insulation region 222. The first insulation region 221 and the second insulation region 222 can be, for example but not limited to, a shallow trench isolation (STI) structure as shown in FIG. 2.

Please still refer to FIG. 2. The first P-type well 261 and the second P-type well 262 are formed in the P-type epitaxial layer 211 by one same ion implantation process step and each of the first P-type well 261 and the second P-type well 262 has a P-type conductivity. The gate 23 is formed on the P-type epitaxial layer 211 within the operation region 22. The gate 23 includes: a conductive layer, a spacer layer and a dielectric layer, wherein the dielectric layer is formed on and in contact with the top surface 21a, which is well known to a person having ordinary skill in the art, so the details thereof are not redundantly explained here. The N-type source 24 and the N-type drain 25 are formed in the P-type epitaxial layer 211 within the operation region 22 by one same ion implantation process step, wherein the N-type source 24 and the N-type drain 25 are located below and outside two sides of the gate 23, respectively, wherein the side of the gate 23 which is closer to the N-type source 24 is a source side and the side of the gate 23 which is closer to the N-type drain 25 is a drain side. The N-type source 24 is located on the first P-type well 261, and the N-type drain 25 is located on the second P-type well 262. The N-type source 24 and the N-type drain 25 are both formed on and in contact with the top surface 21a and each of the N-type source 24 and the N-type drain 25 has an N-type conductivity. The P-type contact pole 212 is formed in the P-type epitaxial layer 211 and is formed below and in contact with the top surface 21a, wherein the P-type contact pole 212 has a P-type conductivity and serves as an electrical contact of the first P-type well 261, the P-type epitaxial layer 211 and the second P-type well 262.

Please still refer to FIG. 2. The first P-type well 261 completely encompasses and is in contact with a lower surface of the N-type source 24. The second P-type well 262 completely encompasses and is in contact with a lower surface of the N-type drain 25. Each of the first P-type well 261 and the second P-type well 262 has a second concentration of P-type doped impurities, wherein the second concentration of P-type doped impurities is higher than the first concentration of P-type doped impurities. In this embodiment, the second concentration of P-type doped impurities is sufficient for preventing a leakage current from flowing between the N-type drain 25 and the P-type substrate 21 while the native NMOS device 20 is in operation.

In one embodiment, the P-type epitaxial layer 211 has a volume resistance which is equal to 45 Ohm-cm.

In one embodiment, within the operation region 22, there is no other N-type region in the P-type epitaxial layer 211, except the N-type source 24 and the N-type drain 25.

Note that the top surface 21a as referred to does not mean a completely flat plane but refers to the surface of the P-type epitaxial layer 211. In the present embodiment, for example, a part of the top surface 21a at the location where the first insulation region 221 is in contact with the P-type epitaxial layer 211 has a recessed portion; a part of the top surface 21a at the location where the second insulation region 222 is in contact with the P-type epitaxial layer 211 also has a recessed portion.

Note that the gate 23 includes a conductive layer which is conductive, a dielectric layer in contact with the top surface 21a, and a spacer layer which is electrically insulative. The conductive layer serves as an electrical contact of the gate 23, and is formed on and in contact with the dielectric layer. The spacer layer is formed out of two sides of the conductive layer, as an electrical insulative layer of the gate 23, which is well known to a person having ordinary skill in the art, so the details thereof are not redundantly explained here.

Note that the above-mentioned “N-type” and “P-type” mean that impurities of corresponding conductivity types are doped in regions of the native NMOS device (for example but not limited to the aforementioned P-type epitaxial layer 211, the aforementioned N-type source 24 and N-type drain 25, the aforementioned first P-type well 261 and second P-type well 262 and the aforementioned P-type contact pole 212, etc.), so that the regions have the corresponding “N-type” or “P-type”, wherein “N-type” and “P-type” are opposite conductivity types.

In addition, the term “native NMOS device” refers to a device whose threshold voltage approximates to zero in normal operation. Such native NMOS device has various applications in circuit designs; for one example, when a native NMOS device is used to constitute a source follower, because the native NMOS device has no voltage drop, it does not need to reserve a margin for headroom. For another example, when a native NMOS device is used to constitute a buffer, it has no DC voltage level offset. These applications and benefits are known to a person having ordinary skill in the art, so the details thereof are not redundantly explained here.

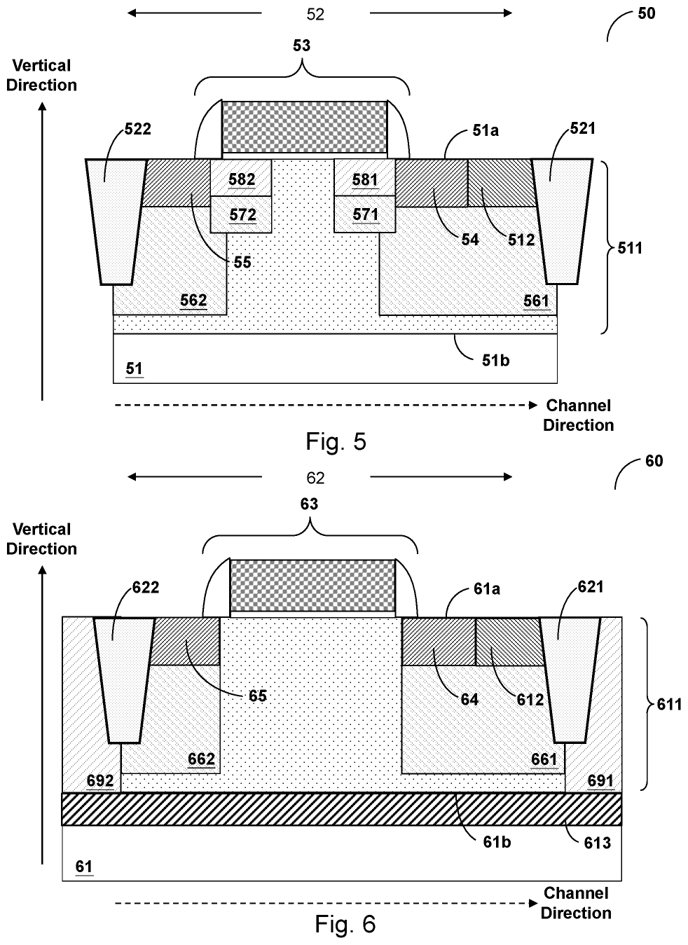

FIG. 3 shows a cross-section view of a native NMOS device 30 according to another embodiment of the present invention. As shown in FIG. 3, the native NMOS device 30 comprises: a P-type epitaxial layer 311, a first insulation region 321, a second insulation region 322, a gate 33, an N-type source 34, an N-type drain 35, a first P-type well 361, a second P-type well 362, a P-type contact pole 312, a first pocket region 371 and a second pocket region 372.

The P-type epitaxial layer 311 is formed on a P-type substrate 31 and has a P-type conductivity, wherein the P-type epitaxial layer 311 has a first concentration of P-type doped impurities. The P-type epitaxial layer 311 has a top surface 31a and a bottom surface 31b that is opposite to the top surface 31a in the vertical direction (as indicated by the direction of the solid arrow in FIG. 3, and all occurrences of the term “vertical direction” in this specification refer to the same direction). The P-type substrate 31 is, for example but not limited to, a P-conductivity type or an N-conductivity type semiconductor substrate. The P-type epitaxial layer 311, for example, is formed on the P-type substrate 31 by an epitaxial growth process step. A part of the P-type epitaxial layer 311 serves to provide a conduction current channel when the native NMOS device 20 operates in the ON operation.

Please still refer to FIG. 3. The first insulation region 321 and the second insulation region 322 are formed on the P-type epitaxial layer 311, wherein the first insulation region 321 and the second insulation region 322 are configured to define an operation region 32 between the first insulation region 321 and the second insulation region 322. The first insulation region 321 and the second insulation region 322 can be, for example but not limited to, a shallow trench isolation (STI) structure as shown in FIG. 3.

Please still refer to FIG. 3. The first P-type well 361 and the second P-type well 362 are formed in the P-type epitaxial layer 311 by one same ion implantation process step and each of the first P-type well 361 and the second P-type well 362 has a P-type conductivity. The gate 33 is formed on the P-type epitaxial layer 311 within the operation region 32. The gate 33 includes: a conductive layer, a spacer layer and a dielectric layer, wherein the dielectric layer is formed on and in contact with the top surface 31a, which is well known to a person having ordinary skill in the art, so the details thereof are not redundantly explained here. The N-type source 34 and the N-type drain 35 are formed in the P-type epitaxial layer 311 within the operation region 32 by one same ion implantation process step, wherein the N-type source 34 and the N-type drain 35 are located below and outside two sides of the gate 33, respectively, wherein the side of the gate 33 which is closer to the N-type source 34 is a source side and the side of the gate 33 which is closer to the N-type drain 35 is a drain side. The N-type source 34 is located on the first P-type well 361, and the N-type drain 35 is located on the second P-type well 362. The N-type source 34 and the N-type drain 35 are both formed on and in contact with the top surface 31a and each of the N-type source 34 and the N-type drain 35 has an N-type conductivity. The P-type contact pole 312 is formed in the P-type epitaxial layer 311 and is formed below and in contact with the top surface 31a, wherein the P-type contact pole 312 has a P-type conductivity and serves as an electrical contact of the first P-type well 361, the P-type epitaxial layer 311 and the second P-type well 362.

Please still refer to FIG. 3. The first P-type well 361 completely encompasses and is in contact with a lower surface of the N-type source 34. The second P-type well 362 completely encompasses and is in contact with a lower surface of the N-type drain 35. Each of the first P-type well 361 and the second P-type well 362 has a second concentration of P-type doped impurities, wherein the second concentration of P-type doped impurities is higher than the first concentration of P-type doped impurities. In this embodiment, the second concentration of P-type doped impurities is sufficient for preventing a leakage current from flowing between the N-type drain 35 and the P-type substrate 31 while the native NMOS device 30 is in operation.

The first pocket region 371 and the second pocket region 372 are located vertically below the gate 33 and are formed in the P-type epitaxial layer 311 outside the first P-type well 361 and the second P-type well 362, respectively, by one same ion implantation process step. Each of the first pocket region 371 and the second pocket region 372 has a third concentration of P-type doped impurities, wherein the third concentration of P-type doped impurities is higher than the first concentration of P-type doped impurities. In this embodiment, the third concentration of P-type doped impurities is sufficient for preventing the leakage current from flowing between the N-type drain 35 and the N-type source 34 while the native NMOS device 30 is OFF.

In one embodiment, the P-type epitaxial layer 311 has a volume resistance which is equal to 45 Ohm-cm.

In one embodiment, within the operation region 32, there is no other N-type region in the P-type epitaxial layer 311, except the N-type source 34 and the N-type drain 35.

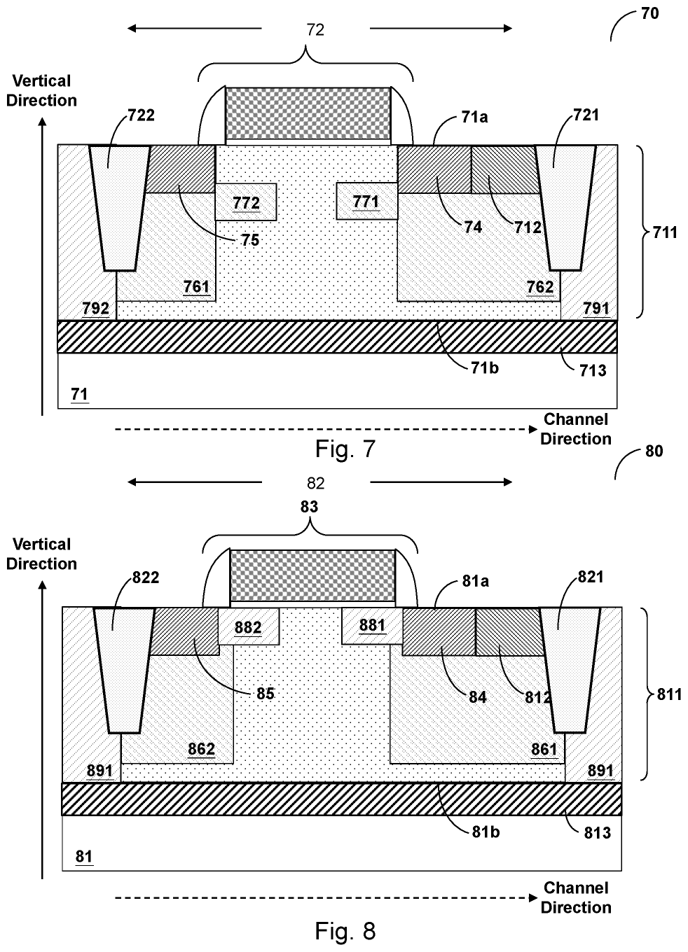

FIG. 4 shows a cross-section view of a native NMOS device 40 according to yet another embodiment of the present invention. As shown in FIG. 4, the native NMOS device 40 comprises: a P-type epitaxial layer 411, a first insulation region 421, a second insulation region 422, a gate 43, an N-type source 44, an N-type drain 45, a first P-type well 461, a second P-type well 462, a P-type contact pole 412, a first N-type lightly doped drain (LDD) 481 and a second N-type LDD 482.

The P-type epitaxial layer 411 is formed on a P-type substrate 41 and has a P-type conductivity, wherein the P-type epitaxial layer 411 has a first concentration of P-type doped impurities. The P-type epitaxial layer 411 has a top surface 41a and a bottom surface 41b that is opposite to the top surface 41a in the vertical direction (as indicated by the direction of the solid arrow in FIG. 4, and all occurrences of the term “vertical direction” in this specification refer to the same direction). The P-type substrate 41 is, for example but not limited to, a P-conductivity type or an N-conductivity type semiconductor substrate. The P-type epitaxial layer 411, for example, is formed on the P-type substrate 41 by an epitaxial growth process step. A part of the P-type epitaxial layer 411 serves to provide a conduction current channel when the native NMOS device 40 operates in the ON operation.

Please still refer to FIG. 4. The first insulation region 421 and the second insulation region 422 are formed on the P-type epitaxial layer 411, wherein the first insulation region 421 and the second insulation region 422 are configured to define an operation region 42 between the first insulation region 421 and the second insulation region 422. The first insulation region 421 and the second insulation region 422 can be, for example but not limited to, a shallow trench isolation (STI) structure as shown in FIG. 4.

Please still refer to FIG. 4. The first P-type well 461 and the second P-type well 462 are formed in the P-type epitaxial layer 411 by one same ion implantation process step and each of the first P-type well 461 and the second P-type well 462 has a P-type conductivity. The gate 43 is formed on the P-type epitaxial layer 411 within the operation region 42. The gate 43 includes: a conductive layer, a spacer layer and a dielectric layer, wherein the dielectric layer is formed on and in contact with the top surface 41a, which is well known to a person having ordinary skill in the art, so the details thereof are not redundantly explained here. The N-type source 44 and the N-type drain 45 are formed in the P-type epitaxial layer 411 within the operation region 42 by one same ion implantation process step, wherein the N-type source 44 and the N-type drain 45 are located below and outside two sides of the gate 43, respectively, wherein the side of the gate 43 which is closer to the N-type source 44 is a source side and the side of the gate 43 which is closer to the N-type drain 45 is a drain side. The N-type source 44 is located on the first P-type well 461, and the N-type drain 45 is located on the second P-type well 462. The N-type source 44 and the N-type drain 45 are both formed on and in contact with the top surface 41a and each of the N-type source 44 and the N-type drain 45 has an N-type conductivity. The P-type contact pole 412 is formed in the P-type epitaxial layer 411 and is formed below and in contact with the top surface 41a, wherein the P-type contact pole 412 has a P-type conductivity and serves as an electrical contact of the first P-type well 461, the P-type epitaxial layer 411 and the second P-type well 462.

Please still refer to FIG. 4. The first P-type well 461 completely encompasses and is in contact with a lower surface of the N-type source 44. The second P-type well 462 completely encompasses and is in contact with a lower surface of the N-type drain 45. Each of the first P-type well 461 and the second P-type well 462 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 45 and the P-type substrate 41 while the native NMOS device 40 is in operation.

The first N-type LDD 481 and the second N-type LDD 482 are located vertically below the gate 43 and are formed in the P-type epitaxial layer 411 outside the N-type source 44 and the N-type drain 45, respectively, by one same ion implantation process step. The first N-type LDD 481 and the second N-type LDD 482 are in contact with a lateral side of the N-type source 44 and a lateral side of the N-type drain 45, respectively, wherein the lateral sides of the N-type source 44 and the N-type drain 45 are in the P-type epitaxial layer 411 which is located vertically below the gate 43. The first N-type LDD 481 and the second N-type LDD 482 serve to attenuate an electrical field of the N-type drain 45, to improve hot carrier injection (HCI) effect.

In one embodiment, the P-type epitaxial layer 411 has a volume resistance which is equal to 45 Ohm-cm.

In one embodiment, within the operation region 42, there is no other N-type region in the P-type epitaxial layer 411, except the N-type source 44, the N-type drain 45, the first N-type LDD 481 and the second N-type LDD 482.

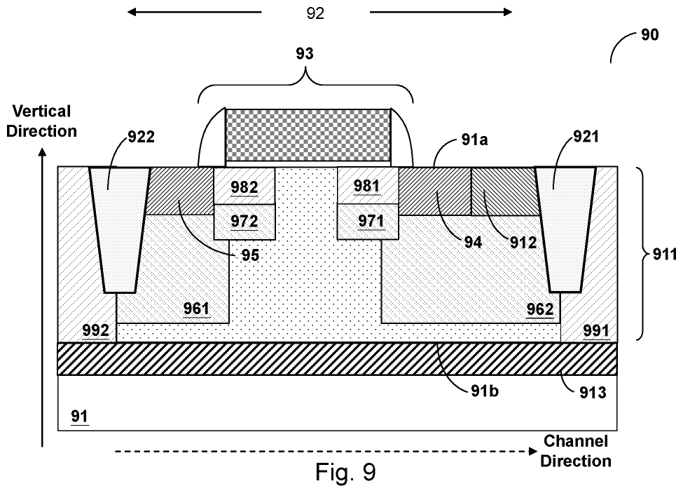

FIG. 5 shows a cross-section view of a native NMOS device 50 according to still another embodiment of the present invention. As shown in FIG. 5, the native NMOS device 50 comprises: a P-type epitaxial layer 511, a first insulation region 521, a second insulation region 522, a gate 53, an N-type source 54, an N-type drain 55, a first P-type well 561, a second P-type well 562, a P-type contact pole 512, a first pocket region 571, a second pocket region 572, a first N-type LDD 581 and a second N-type LDD 582.

The P-type epitaxial layer 511 is formed on a P-type substrate 51 and has a P-type conductivity, wherein the P-type epitaxial layer 511 has a first concentration of P-type doped impurities. The P-type epitaxial layer 511 has a top surface 51a and a bottom surface 51b that is opposite to the top surface 51a in the vertical direction (as indicated by the direction of the solid arrow in FIG. 5, and all occurrences of the term “vertical direction” in this specification refer to the same direction). The P-type substrate 51 is, for example but not limited to, a P-conductivity type or an N-conductivity type semiconductor substrate. The P-type epitaxial layer 511, for example, is formed on the P-type substrate 51 by an epitaxial growth process step. A part of the P-type epitaxial layer 511 serves to provide a conduction current channel when the native NMOS device 50 operates in the ON operation.

Please still refer to FIG. 5. The first insulation region 521 and the second insulation region 522 are formed on the P-type epitaxial layer 511, wherein the first insulation region 521 and the second insulation region 522 are configured to define an operation region 52 between the first insulation region 521 and the second insulation region 522. The first insulation region 521 and the second insulation region 522 can be, for example but not limited to, a shallow trench isolation (STI) structure as shown in FIG. 5.

Please still refer to FIG. 5. The first P-type well 561 and the second P-type well 562 are formed in the P-type epitaxial layer 511 by one same ion implantation process step and each of the first P-type well 561 and the second P-type well 562 has a P-type conductivity. The gate 53 is formed on the P-type epitaxial layer 511 within the operation region 52. The gate 53 includes: a conductive layer, a spacer layer and a dielectric layer, wherein the dielectric layer is formed on and in contact with the top surface 21a, which is well known to a person having ordinary skill in the art, so the details thereof are not redundantly explained here. The N-type source 54 and the N-type drain 55 are formed in the P-type epitaxial layer 511 within the operation region 52 by one same ion implantation process step, wherein the N-type source 54 and the N-type drain 55 are located below and outside two sides of the gate 53, respectively, wherein the side of the gate 53 which is closer to the N-type source 54 is a source side and the side of the gate 53 which is closer to the N-type drain 55 is a drain side. The N-type source 54 is located on the first P-type well 561, and the N-type drain 55 is located on the second P-type well 562. The N-type source 54 and the N-type drain 55 are both formed on and in contact with the top surface 51a and each of the N-type source 24 and the N-type drain 25 has an N-type conductivity. The P-type contact pole 512 is formed in the P-type epitaxial layer 511 and is formed below and in contact with the top surface 51a, wherein the P-type contact pole 512 has a P-type conductivity and serves as an electrical contact of the first P-type well 561, the P-type epitaxial layer 511 and the second P-type well 562.

Please still refer to FIG. 5. The first P-type well 561 completely encompasses and is in contact with a lower surface of the N-type source 54. The second P-type well 562 completely encompasses and is in contact with a lower surface of the N-type drain 55. Each of the first P-type well 561 and the second P-type well 562 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 55 and the P-type substrate 51 while the native NMOS device 50 is in operation.

The first pocket region 571 and the second pocket region 572 are located vertically below the gate 53 and are formed in the P-type epitaxial layer 511 outside the first P-type well 561 and the second P-type well 562, respectively, by one same ion implantation process step. Each of the first pocket region 571 and the second pocket region 572 has a third concentration of P-type doped impurities, and wherein the third concentration of P-type doped impurities is higher than the first concentration of P-type doped impurities. In this embodiment, the third concentration of P-type doped impurities is sufficient for preventing the leakage current from flowing between the N-type drain 55 and the N-type source 54 while the native NMOS device 50 is OFF.

The first N-type LDD 581 and the second N-type LDD 582 are located vertically below the gate 53 and are formed in the P-type epitaxial layer 511 outside the N-type source 54 and the N-type drain 55, respectively, by one same ion implantation process step. The first N-type LDD 581 and the second N-type LDD 582 are in contact with a lateral side of the N-type source 54 and a lateral side of the N-type drain 55, respectively, wherein the lateral sides of the N-type source 54 and the N-type drain 55 are in the P-type epitaxial layer 511 which is located vertically below the gate 53. The first N-type LDD 581 and the second N-type LDD 582 serve to attenuate an electrical field of the N-type drain 45, to improve hot carrier injection (HCI) effect.

In one embodiment, the P-type epitaxial layer 511 has a volume resistance which is equal to 45 Ohm-cm.

In one embodiment, within the operation region 52, there is no other N-type region in the P-type epitaxial layer 511, except the N-type source 54 and the N-type drain 55, the first N-type LDD 581 and the second N-type LDD 582.

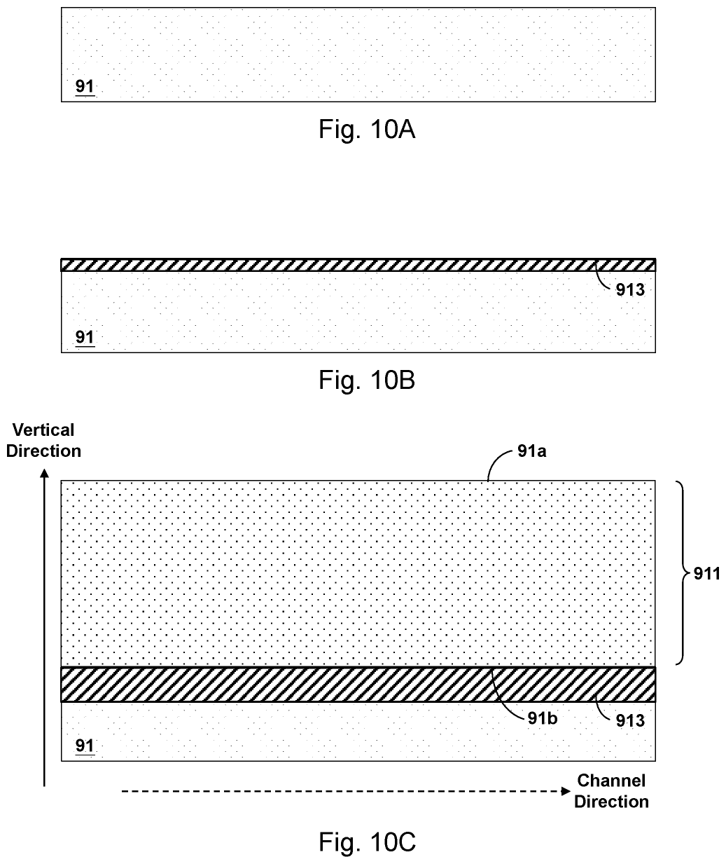

FIG. 6 shows a cross-section view of a native NMOS device 60 according to still another embodiment of the present invention. As shown in FIG. 6, the native NMOS device 60 comprises: a P-type epitaxial layer 611, an N-type buried layer 613, a first insulation region 621, a second insulation region 622, a gate 63, an N-type source 64, an N-type drain 65, a first P-type well 661, a second P-type well 662, a P-type contact pole 612, a first isolation region 691 and a second isolation region 692.

The P-type epitaxial layer 611 is formed on a P-type substrate 61 and has a P-type conductivity, wherein the P-type epitaxial layer 611 has a first concentration of P-type doped impurities. The P-type epitaxial layer 611 has a top surface 61a and a bottom surface 61b that is opposite to the top surface 61a in the vertical direction (as indicated by the direction of the solid arrow in FIG. 6, and all occurrences of the term “vertical direction” in this specification refer to the same direction). The P-type substrate 61 is, for example but not limited to, a P-conductivity type or an N-conductivity type semiconductor substrate. The P-type epitaxial layer 611, for example, is formed on the P-type substrate 61 by an epitaxial growth process step. A part of the P-type epitaxial layer 611 serves to provide a conduction current channel when the native NMOS device 60 operates in the ON operation.

The N-type buried layer 613 is formed below and in contact with the P-type epitaxial layer 611, wherein the N-type buried layer 613 completely encompasses the P-type epitaxial layer 611 within the operation region 62.

Please still refer to FIG. 6. The first insulation region 621 and the second insulation region 622 are formed on the P-type epitaxial layer 611, wherein the first insulation region 621 and the second insulation region 622 are configured to define an operation region 62 between the first insulation region 621 and the second insulation region 622. The first insulation region 621 and the second insulation region 622 can be, for example but not limited to, a shallow trench isolation (STI) structure as shown in FIG. 6.

Please still refer to FIG. 6. The first P-type well 661 and the second P-type well 662 are formed in the P-type epitaxial layer 611 by one same ion implantation process step and each of the first P-type well 661 and the second P-type well 662 has a P-type conductivity. The gate 63 is formed on the P-type epitaxial layer 611 within the operation region 62. The gate 63 includes: a conductive layer, a spacer layer and a dielectric layer, wherein the dielectric layer is formed on and in contact with the top surface 61a, which is well known to a person having ordinary skill in the art, so the details thereof are not redundantly explained here. The N-type source 64 and the N-type drain 65 are formed in the P-type epitaxial layer 611 within the operation region 62 by one same ion implantation process step, wherein the N-type source 64 and the N-type drain 65 are located below and outside two sides of the gate 63, respectively, wherein the side of the gate 63 which is closer to the N-type source 64 is a source side and the side of the gate 63 which is closer to the N-type drain 65 is a drain side. The N-type source 64 is located on the first P-type well 661, and the N-type drain 65 is located on the second P-type well 662. The N-type source 64 and the N-type drain 65 are both formed on and in contact with the top surface 61a and each of the N-type source 64 and the N-type drain 65 has an N-type conductivity. The P-type contact pole 612 is formed in the P-type epitaxial layer 611 and is formed below and in contact with the top surface 61a, wherein the P-type contact pole 612 has a P-type conductivity and serves as an electrical contact of the first P-type well 661, the P-type epitaxial layer 611 and the second P-type well 662.

Please still refer to FIG. 6. The first P-type well 661 completely encompasses and is in contact with a lower surface of the N-type source 64. The second P-type well 662 completely encompasses and is in contact with a lower surface of the N-type drain 65. Each of the first P-type well 661 and the second P-type well 662 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 65 and the P-type substrate 61 while the native NMOS device 60 is in operation.

The first isolation region 691 and the second isolation region 692 are located on the N-type buried layer 613 and are formed in the P-type epitaxial layer 611 outside the first insulation region 621 and the second insulation region 622, respectively, by one same ion implantation process step. Both the first isolation region 691 and the second isolation region 692 are not within the operation region 62. In the P-type epitaxial layer 611, the N-type buried layer 613, the first isolation region 691 and the second isolation region 692 together constitute an isolation region which entirely encapsulates the operation region 62, and such formed isolation region serves to electrically isolate the native NMOS device 60 from other semiconductor devices formed in the P-type epitaxial layer 611.

In one embodiment, the P-type epitaxial layer 611 has a volume resistance which is equal to 45 Ohm-cm.

In one embodiment, within the operation region 62, there is no other N-type region in the P-type epitaxial layer 611, except the N-type source 64 and the N-type drain 65.

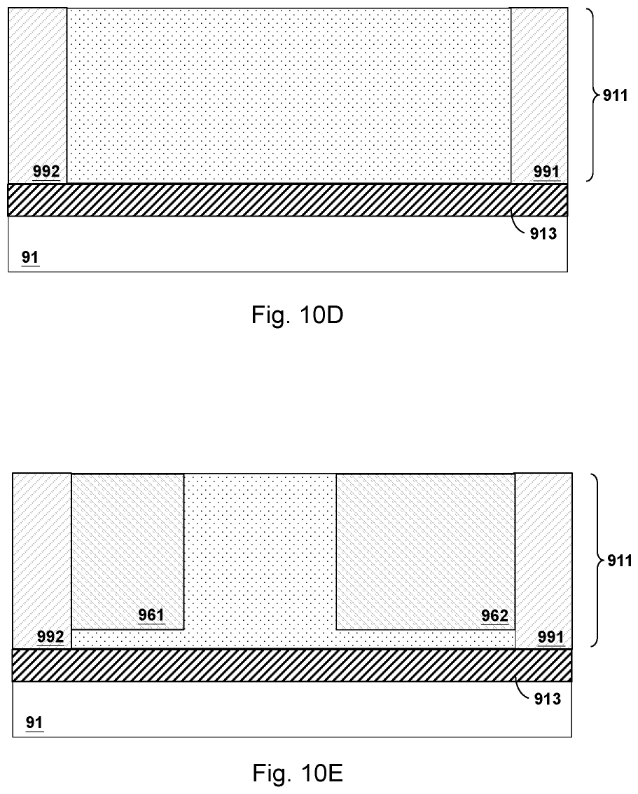

FIG. 7 shows a cross-section view of a native NMOS device 70 according to still another embodiment of the present invention. As shown in FIG. 7, the native NMOS device 70 comprises: a P-type epitaxial layer 711, an N-type buried layer 713, a first insulation region 721, a second insulation region 722, a gate 73, an N-type source 74, an N-type drain 75, a first P-type well 761, a second P-type well 762, a P-type contact pole 712, a first isolation region 791, a second isolation region 792, a first pocket region 771 and a second pocket region 772.

The P-type epitaxial layer 711 is formed on a P-type substrate 71 and has a P-type conductivity, wherein the P-type epitaxial layer 711 has a first concentration of P-type doped impurities. The P-type epitaxial layer 711 has a top surface 71a and a bottom surface 71b that is opposite to the top surface 71a in the vertical direction (as indicated by the direction of the solid arrow in FIG. 7, and all occurrences of the term “vertical direction” in this specification refer to the same direction). The P-type substrate 71 is, for example but not limited to, a P-conductivity type or an N-conductivity type semiconductor substrate. The P-type epitaxial layer 711, for example, is formed on the P-type substrate 71 by an epitaxial growth process step. A part of the P-type epitaxial layer 711 serves to provide a conduction current channel when the native NMOS device 70 operates in the ON operation.

The N-type buried layer 713 is formed below and in contact with the P-type epitaxial layer 711, wherein the N-type buried layer 713 completely encompasses the P-type epitaxial layer 711 within the operation region 72.

Please still refer to FIG. 7. The first insulation region 721 and the second insulation region 722 are formed on the P-type epitaxial layer 711, wherein the first insulation region 721 and the second insulation region 722 are configured to define an operation region 72 between the first insulation region 721 and the second insulation region 722. The first insulation region 721 and the second insulation region 722 can be, for example but not limited to, a shallow trench isolation (STI) structure as shown in FIG. 7.

Please still refer to FIG. 7. The first P-type well 761 and the second P-type well 762 are formed in the P-type epitaxial layer 711 by one same ion implantation process step and each of the first P-type well 761 and the second P-type well 762 has a P-type conductivity. The gate 73 is formed on the P-type epitaxial layer 711 within the operation region 72. The gate 73 includes: a conductive layer, a spacer layer and a dielectric layer, wherein the dielectric layer is formed on and in contact with the top surface 71a, which is well known to a person having ordinary skill in the art, so the details thereof are not redundantly explained here. The N-type source 74 and the N-type drain 75 are formed in the P-type epitaxial layer 711 within the operation region 72 by one same ion implantation process step, wherein the N-type source 74 and the N-type drain 75 are located below and outside two sides of the gate 73, respectively, wherein the side of the gate 73 which is closer to the N-type source 74 is a source side and the side of the gate 73 which is closer to the N-type drain 75 is a drain side. The N-type source 74 is located on the first P-type well 761, and the N-type drain 75 is located on the second P-type well 762. The N-type source 74 and the N-type drain 75 are both formed on and in contact with the top surface 71a and each of the N-type source 74 and the N-type drain 75 has an N-type conductivity. The P-type contact pole 712 is formed in the P-type epitaxial layer 711 and is formed below and in contact with the top surface 71a, wherein the P-type contact pole 712 has a P-type conductivity and serves as an electrical contact of the first P-type well 761, the P-type epitaxial layer 711 and the second P-type well 762.

Please still refer to FIG. 7. The first P-type well 761 completely encompasses and is in contact with a lower surface of the N-type source 74. The second P-type well 762 completely encompasses and is in contact with a lower surface of the N-type drain 75. Each of the first P-type well 761 and the second P-type well 762 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 75 and the P-type substrate 71 while the native NMOS device 70 is in operation.

The first isolation region 791 and the second isolation region 792 are located on the N-type buried layer 713 and are formed in the P-type epitaxial layer 711 outside the first insulation region 721 and the second insulation region 722, respectively, by one same ion implantation process step. Both the first isolation region 791 and the second isolation region 792 are not within the operation region 72. In the P-type epitaxial layer 711, the N-type buried layer 713, the first isolation region 791 and the second isolation region 792 together constitute an isolation region which entirely encapsulates the operation region 72, and such formed isolation region serves to electrically isolate the native NMOS device 70 from other semiconductor devices formed in the P-type epitaxial layer 711.

The first pocket region 771 and the second pocket region 772 are located vertically below the gate 73 and are formed in the P-type epitaxial layer 711 outside the first P-type well 761 and the second P-type well 762, respectively, by one same ion implantation process step. Each of the first pocket region 771 and the second pocket region 772 has a third concentration of P-type doped impurities, and wherein the third concentration of P-type doped impurities is higher than the first concentration of P-type doped impurities. In this embodiment, the third concentration of P-type doped impurities is sufficient for preventing the leakage current from flowing between the N-type drain 75 and the N-type source 74 while the native NMOS device 70 is OFF.

In one embodiment, the P-type epitaxial layer 711 has a volume resistance which is equal to 45 Ohm-cm.

In one embodiment, within the operation region 72, there is no other N-type region in the P-type epitaxial layer 711, except the N-type source 74 and the N-type drain 75.

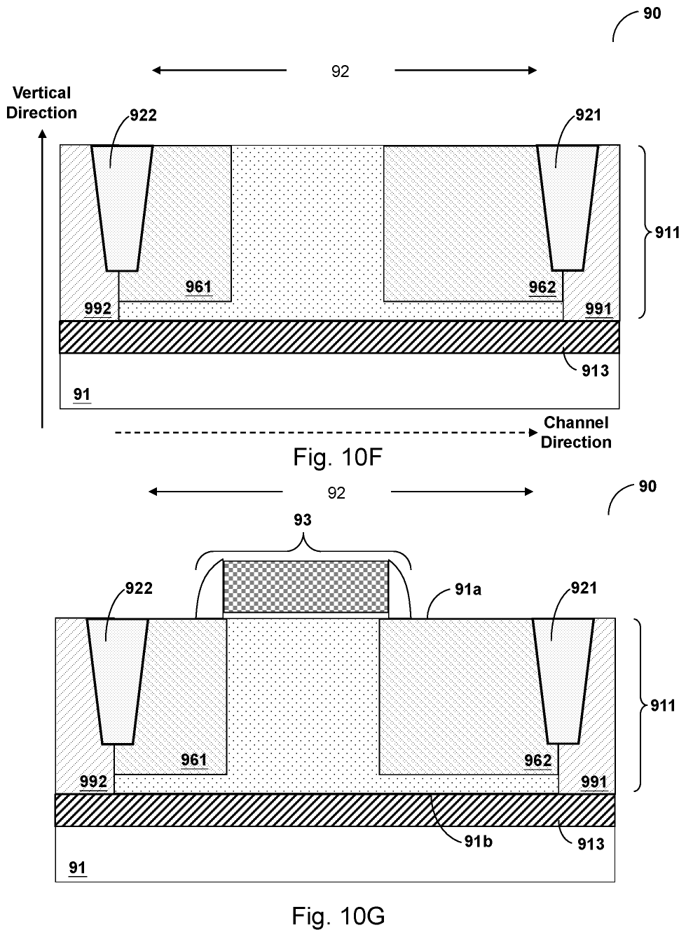

FIG. 8 shows a cross-section view of a native NMOS device 80 according to still another embodiment of the present invention. As shown in FIG. 8, the native NMOS device 80 comprises: a P-type epitaxial layer 811, an N-type buried layer 813, a first insulation region 821, a second insulation region 822, a gate 83, an N-type source 84, an N-type drain 85, a first P-type well 861, a second P-type well 862, a P-type contact pole 812, a first N-type LDD 881, a second N-type LDD 882, a first isolation region 891 and a second isolation region 892.

The P-type epitaxial layer 811 is formed on a P-type substrate 81 and has a P-type conductivity, wherein the P-type epitaxial layer 811 has a first concentration of P-type doped impurities. The P-type epitaxial layer 811 has a top surface 81a and a bottom surface 81b that is opposite to the top surface 81a in the vertical direction (as indicated by the direction of the solid arrow in FIG. 8, and all occurrences of the term “vertical direction” in this specification refer to the same direction). The P-type substrate 81 is, for example but not limited to, a P-conductivity type or an N-conductivity type semiconductor substrate. The P-type epitaxial layer 811, for example, is formed on the P-type substrate 81 by an epitaxial growth process step. A part of the P-type epitaxial layer 811 serves to provide a conduction current channel when the native NMOS device 80 operates in the ON operation.

The N-type buried layer 813 is formed below and in contact with the P-type epitaxial layer 811, wherein the N-type buried layer 813 completely encompasses the P-type epitaxial layer 811 within the operation region 82.

Please still refer to FIG. 8. The first insulation region 821 and the second insulation region 822 are formed on the P-type epitaxial layer 811, wherein the first insulation region 821 and the second insulation region 822 are configured to define an operation region 82 between the first insulation region 821 and the second insulation region 822. The first insulation region 821 and the second insulation region 822 can be, for example but not limited to, a shallow trench isolation (STI) structure as shown in FIG. 8.

Please still refer to FIG. 8. The first P-type well 861 and the second P-type well 862 are formed in the P-type epitaxial layer 811 by one same ion implantation process step and each of the first P-type well 861 and the second P-type well 862 has a P-type conductivity. The gate 83 is formed on the P-type epitaxial layer 811 within the operation region 82. The gate 83 includes: a conductive layer, a spacer layer and a dielectric layer, wherein the dielectric layer is formed on and in contact with the top surface 81a, which is well known to a person having ordinary skill in the art, so the details thereof are not redundantly explained here. The N-type source 84 and the N-type drain 85 are formed in the P-type epitaxial layer 811 within the operation region 82 by one same ion implantation process step, wherein the N-type source 84 and the N-type drain 85 are located below and outside two sides of the gate 83, respectively, wherein the side of the gate 83 which is closer to the N-type source 84 is a source side and the side of the gate 83 which is closer to the N-type drain 85 is a drain side. The N-type source 84 is located on the first P-type well 861, and the N-type drain 85 is located on the second P-type well 862. The N-type source 84 and the N-type drain 85 are both formed on and in contact with the top surface 81a and each of the N-type source 84 and the N-type drain 85 has an N-type conductivity. The P-type contact pole 812 is formed in the P-type epitaxial layer 811 and is formed below and in contact with the top surface 81a, wherein the P-type contact pole 812 has a P-type conductivity and serves as an electrical contact of the first P-type well 861, the P-type epitaxial layer 811 and the second P-type well 862.

Please still refer to FIG. 8. The first P-type well 861 completely encompasses and is in contact with a lower surface of the N-type source 84. The second P-type well 862 completely encompasses and is in contact with a lower surface of the N-type drain 85. Each of the first P-type well 861 and the second P-type well 862 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 85 and the P-type substrate 81 while the native NMOS device 80 is in operation.

The first isolation region 891 and the second isolation region 892 are located on the N-type buried layer 813 and are formed in the P-type epitaxial layer 811 outside the first insulation region 821 and the second insulation region 822, respectively, by one same ion implantation process step. Both the first isolation region 891 and the second isolation region 892 are not within the operation region 82. In the P-type epitaxial layer 811, the N-type buried layer 813, the first isolation region 891 and the second isolation region 892 together constitute an isolation region which entirely encapsulates the operation region 82, and such formed isolation region serves to electrically isolate the native NMOS device 80 from other semiconductor devices formed in the P-type epitaxial layer 811.

The first N-type LDD 881 and the second N-type LDD 882 are located vertically below the gate 83 and are formed in the P-type epitaxial layer 811 outside the N-type source 84 and the N-type drain 85, respectively, by one same ion implantation process step. The first N-type LDD 881 and the second N-type LDD 882 are in contact with a lateral side of the N-type source 84 and a lateral side of the N-type drain 85, respectively, wherein the lateral sides of the N-type source 84 and the N-type drain 85 are in the P-type epitaxial layer 411 which is located vertically below the gate 83. The first N-type LDD 881 and the second N-type LDD 882 serve to attenuate an electrical field of the N-type drain 85, to improve hot carrier injection (HCI) effect.

In one embodiment, the P-type epitaxial layer 211 has a volume resistance which is equal to 45 Ohm-cm.

In one embodiment, within the operation region 82, there is no other N-type region in the P-type epitaxial layer 811, except the N-type source 84 and the N-type drain 85, the first N-type LDD 881 and the second N-type LDD 882.

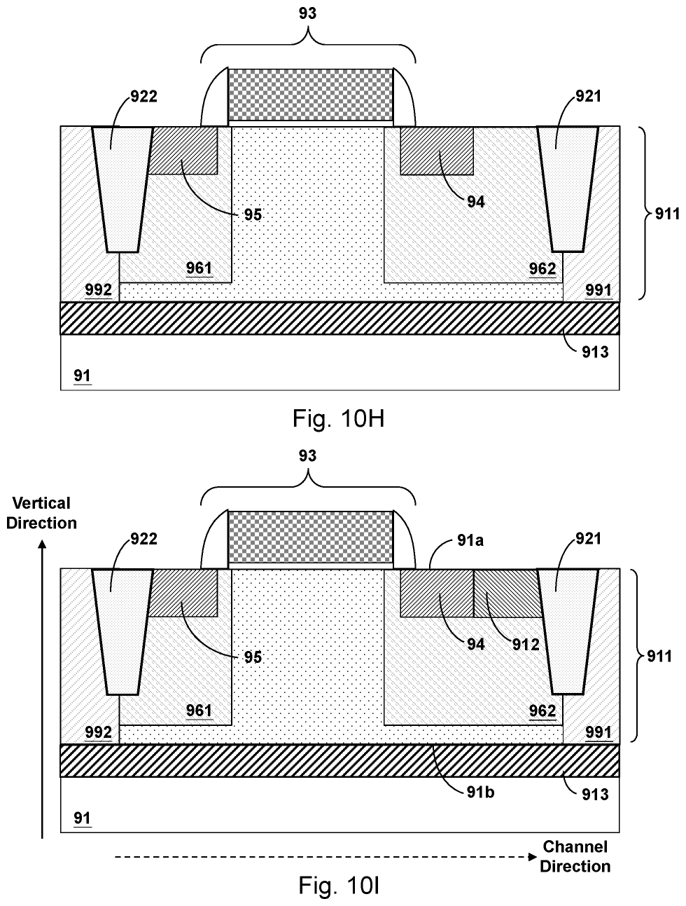

FIG. 9 shows a cross-section view of a native NMOS device 90 according to still another embodiment of the present invention. As shown in FIG. 9, the native NMOS device 90 comprises: a P-type epitaxial layer 911, an N-type buried layer 913, a first insulation region 921, a second insulation region 922, a gate 93, an N-type source 94, an N-type drain 95, a first P-type well 961, a second P-type well 962, a P-type contact pole 912, a first pocket region 971, a second pocket region 972, a first N-type LDD 981, a second N-type LDD 982, a first isolation region 991 and a second isolation region 992.

The P-type epitaxial layer 911 is formed on a P-type substrate 91 and has a P-type conductivity, wherein the P-type epitaxial layer 911 has a first concentration of P-type doped impurities. The P-type epitaxial layer 911 has a top surface 91a and a bottom surface 91b that is opposite to the top surface 91a in the vertical direction (as indicated by the direction of the solid arrow in FIG. 9, and all occurrences of the term “vertical direction” in this specification refer to the same direction). The P-type substrate 91 is, for example but not limited to, a P-conductivity type or an N-conductivity type semiconductor substrate. The P-type epitaxial layer 911, for example, is formed on the P-type substrate 91 by an epitaxial growth process step. A part of the P-type epitaxial layer 911 serves to provide a conduction current channel when the native NMOS device 90 operates in the ON operation.

The N-type buried layer 913 is formed below and in contact with the P-type epitaxial layer 911, wherein the N-type buried layer 913 completely encompasses the P-type epitaxial layer 911 within the operation region 92.

Please still refer to FIG. 9. The first insulation region 921 and the second insulation region 922 are formed on the P-type epitaxial layer 911, wherein the first insulation region 921 and the second insulation region 922 are configured to define an operation region 92 between the first insulation region 921 and the second insulation region 922. The first insulation region 921 and the second insulation region 922 can be, for example but not limited to, a shallow trench isolation (STI) structure as shown in FIG. 9.

Please still refer to FIG. 9. The first P-type well 961 and the second P-type well 962 are formed in the P-type epitaxial layer 911 by one same ion implantation process step and each of the first P-type well 961 and the second P-type well 962 has a P-type conductivity. The gate 93 is formed on the P-type epitaxial layer 911 within the operation region 92. The gate 93 includes: a conductive layer, a spacer layer and a dielectric layer, wherein the dielectric layer is formed on and in contact with the top surface 91a, which is well known to a person having ordinary skill in the art, so the details thereof are not redundantly explained here. The N-type source 94 and the N-type drain 95 are formed in the P-type epitaxial layer 911 within the operation region 92 by one same ion implantation process step, wherein the N-type source 94 and the N-type drain 95 are located below and outside two sides of the gate 93, respectively, wherein the side of the gate 93 which is closer to the N-type source 94 is a source side and the side of the gate 93 which is closer to the N-type drain 95 is a drain side. The N-type source 94 is located on the first P-type well 961, and the N-type drain 95 is located on the second P-type well 962. The N-type source 94 and the N-type drain 95 are both formed on and in contact with the top surface 91a and each of the N-type source 94 and the N-type drain 95 has an N-type conductivity. The P-type contact pole 912 is formed in the P-type epitaxial layer 911 and is formed below and in contact with the top surface 91a, wherein the P-type contact pole 912 has a P-type conductivity and serves as an electrical contact of the first P-type well 961, the P-type epitaxial layer 911 and the second P-type well 962.

Please still refer to FIG. 9. The first P-type well 961 completely encompasses and is in contact with a lower surface of the N-type source 94. The second P-type well 962 completely encompasses and is in contact with a lower surface of the N-type drain 95. Each of the first P-type well 961 and the second P-type well 962 has a second concentration of P-type doped impurities, and wherein the second concentration of P-type doped impurities is higher than the first concentration of P-type doped impurities. In this embodiment, the second concentration of P-type doped impurities is sufficient for preventing a leakage current from flowing between the N-type drain 95 and the P-type substrate 91 while the native NMOS device 90 is in operation.

The first isolation region 991 and the second isolation region 992 are located on the N-type buried layer 913 and are formed in the P-type epitaxial layer 911 outside the first insulation region 921 and the second insulation region 922, respectively, by one same ion implantation process step. Both the first isolation region 991 and the second isolation region 992 are not within the operation region 92. In the P-type epitaxial layer 911, the N-type buried layer 913, the first isolation region 991 and the second isolation region 992 together constitute an isolation region which entirely encapsulates the operation region 92, and such formed isolation region serves to electrically isolate the native NMOS device 90 from other semiconductor devices formed in the P-type epitaxial layer 911.

The first pocket region 971 and the second pocket region 972 are located vertically below the gate 93 and are formed in the P-type epitaxial layer 911 outside the first P-type well 961 and the second P-type well 962, respectively, by one same ion implantation process step. Each of the first pocket region 971 and the second pocket region 972 has a third concentration of P-type doped impurities, and wherein the third concentration of P-type doped impurities is higher than the first concentration of P-type doped impurities. In this embodiment, the third concentration of P-type doped impurities is sufficient for preventing the leakage current from flowing between the N-type drain 95 and the N-type source 94 while the native NMOS device 90 is OFF.

The first N-type LDD 981 and the second N-type LDD 982 are located vertically below the gate 93 and are formed in the P-type epitaxial layer 911 outside the N-type source 94 and the N-type drain 95, respectively, by one same ion implantation process step. The first N-type LDD 981 and the second N-type LDD 982 are in contact with a lateral side of the N-type source 94 and a lateral side of the N-type drain 95, respectively, wherein the lateral sides of the N-type source 94 and the N-type drain 95 are in the P-type epitaxial layer 911 which is located vertically below the gate 93. The first N-type LDD 981 and the second N-type LDD 982 serve to attenuate an electrical field of the N-type drain 95, to improve hot carrier injection (HCI) effect.

In one embodiment, the P-type epitaxial layer 911 has a volume resistance which is equal to 45 Ohm-cm.

In one embodiment, within the operation region 92, there is no other N-type region in the P-type epitaxial layer 911, except the N-type source 94 and the N-type drain 95, the first N-type LDD 981 and the second N-type LDD 982.

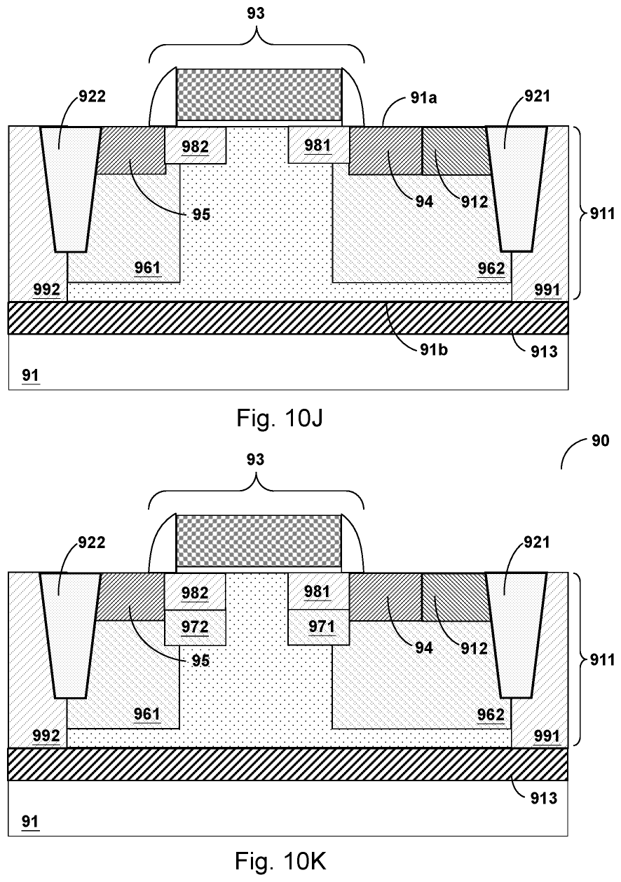

Please refer to FIG. 10A to FIG. 10K, which show cross-section views of a manufacturing method of a native NMOS device 90 according to an embodiment of the present invention. As shown in FIG. 10A, first, a P-type substrate 91 is provided. Next, as shown in FIG. 10B, N-type conductivity impurities are implanted in the P-type substrate 91 in the form of accelerated ions by, for example but not limited to, an ion implantation process step. An N-type buried layer 913 is formed by a thermal diffusion process step during or subsequent to the formation of a P-type epitaxial layer 911 (as shown in FIG. 10C).

Next, referring to FIG. 10C, the P-type epitaxial layer 911 is formed on the P-type substrate 91. The P-type epitaxial layer 911, for example, is formed on the P-type substrate 91 by an epitaxial growth process step. As mentioned above, the N-type buried layer 913 is formed by a thermal diffusion process step during or subsequent to the formation of the P-type epitaxial layer 911. The P-type epitaxial layer 911 has a first concentration of P-type doped impurities. The P-type epitaxial layer 911 has a top surface 91a and a bottom surface 91b that is opposite to the top surface 91a in the vertical direction (as indicated by the direction of the solid arrow in FIG. 9). The P-type substrate 91 is, for example but not limited to, a P-conductivity type semiconductor substrate. A part of the P-type epitaxial layer 911 serves to provide a conduction current channel when the native NMOS device 90 operates in the ON operation.

Next, referring to FIG. 10D, a first isolation region 991 and a second isolation region 992 are formed on the N-type buried layer 913 and are formed in the P-type epitaxial layer 911 outside a first insulation region 921 and a second insulation region 922 (both of which will be formed later), respectively, by for example one same ion implantation process step. Both the first isolation region 991 and the second isolation region 992 are not within the operation region 92. In the P-type epitaxial layer 911, the N-type buried layer 913, the first isolation region 991 and the second isolation region 992 together constitute an isolation region which entirely encapsulates the operation region 92, and such formed isolation region serves to electrically isolate the native NMOS device 90 from other semiconductor devices formed in the P-type epitaxial layer 911.

Next, referring to FIG. 10E, a first P-type well 961 and a second P-type well 962 are formed in the P-type epitaxial layer 911 by for example one same ion implantation process step and each of the first P-type well 961 and the second P-type well 962 has a P-type conductivity.

Next, referring to FIG. 10F, a first insulation region 921 and a second insulation region 922 are formed on the P-type epitaxial layer 911 by for example one same process step, wherein the first insulation region 921 and the second insulation region 922 are configured to define an operation region 92 between the first insulation region 921 and the second insulation region 922. The first insulation region 921 and the second insulation region 922 can be, for example but not limited to, a shallow trench isolation (STI) structure as shown in FIG. 10F.

Next, referring to FIG. 10G, a gate 93 is formed on the P-type epitaxial layer 911 within the operation region 92. The gate 93 includes: a conductive layer, a spacer layer and a dielectric layer, wherein the dielectric layer is formed on and in contact with the top surface 91a, which is well known to a person having ordinary skill in the art, so the details thereof are not redundantly explained here.

Next, referring to FIG. 10H, subsequent to the formation of the gate 93, an N-type source 94 and an N-type drain 95 are formed in the P-type epitaxial layer 911 within the operation region 92 by for example but not limited to one same ion implantation process step, wherein the N-type source 94 and the N-type drain 95 are formed below and outside two sides of the gate 93, respectively, wherein the side of the gate 93 which is closer to the N-type source 94 is a source side and the side of the gate 93 which is closer to the N-type drain 95 is a drain side. The N-type source 94 is located on the first P-type well 961, and the N-type drain 95 is located on the second P-type well 962. The N-type source 94 and the N-type drain 95 are both formed on and in contact with the top surface 91a and each of the N-type source 94 and the N-type drain 95 has an N-type conductivity.

Next, referring to FIG. 10I, a P-type contact pole 912 is formed in the P-type epitaxial layer 911 by for example but not limited to an ion implantation process step and is formed below and in contact with the top surface 91a, wherein the P-type contact pole 912 has a P-type conductivity and serves as an electrical contact of the first P-type well 961, the P-type epitaxial layer 911 and the second P-type well 962. The P-type contact pole 912 and the N-type source 94 are adjacently connected to each other in a channel direction (as indicated by the direction of the dashed arrow in FIG. 10I).

Next, referring to FIG. 10J, a first N-type LDD 981 and a second N-type LDD 982 are formed vertically below the gate 93 and are formed in the P-type epitaxial layer 911 outside the N-type source 94 and the N-type drain 95, respectively, by one same ion implantation process step. The first N-type LDD 981 and the second N-type LDD 982 are in contact with a lateral side of the N-type source 94 and a lateral side of the N-type drain 95, respectively, wherein the lateral sides of the N-type source 94 and the N-type drain 95 are in the P-type epitaxial layer 911 which is located vertically below the gate 93. The first N-type LDD 981 and the second N-type LDD 982 serve to attenuate an electrical field of the N-type drain 95, to improve hot carrier injection (HCI) effect. In the vertical direction, the first N-type LDD 981 and the second N-type LDD 982 are formed below and in contact with the top surface 91a.

Next, referring to FIG. 10K, a first pocket region 971 and a second pocket region 972 are formed vertically below the gate 93 and are formed in the P-type epitaxial layer 911 outside the first P-type well 961 and the second P-type well 962, respectively, by one same ion implantation process step. Each of the first pocket region 971 and the second pocket region 972 has a third concentration of P-type doped impurities, and wherein the third concentration of P-type doped impurities is higher than the first concentration of P-type doped impurities. In this embodiment, the third concentration of P-type doped impurities is sufficient for preventing the leakage current from flowing between the N-type drain 95 and the N-type source 94 while the native NMOS device 90 is OFF.

In one embodiment, the P-type epitaxial layer 911 has a volume resistance which is equal to 45 Ohm-cm.

In one embodiment, within the operation region 92, there is no other N-type region in the P-type epitaxial layer 911, except the N-type source 94 and the N-type drain 95, the first N-type LDD 981 and the second N-type LDD 982.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a deep well region, may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A native NMOS device, comprising:
a P-type epitaxial layer, which is formed on a P-type substrate, wherein the P-type epitaxial layer has a first concentration of P-type doped impurities;
a first insulation region and a second insulation region, both of which are formed on the P-type epitaxial layer, wherein the first insulation region and the second insulation region are configured to define an operation region between the first insulation region and the second insulation region;
a first P-type well and a second P-type well, both of which are formed in the P-type epitaxial layer by one same ion implantation process step;
a gate, which is formed on the P-type epitaxial layer within the operation region; and
an N-type source and an N-type drain, both of which are formed in the P-type epitaxial layer within the operation region by one same ion implantation process step, wherein the N-type source and the N-type drain are located below and outside two sides of the gate, respectively, wherein the side of the gate which is closer to the N-type source is a source side and the side of the gate which is closer to the N-type drain is a drain side, and wherein the N-type source is located on the first P-type well, and the N-type drain is located on the second P-type well;
wherein the first P-type well completely encompasses and is in contact with a lower surface of the N-type source;
wherein the second P-type well completely encompasses and is in contact with a lower surface of the N-type drain;
wherein each of the first P-type well and the second P-type well has a second concentration of P-type doped impurities, and wherein the second concentration of P-type doped impurities is higher than the first concentration of P-type doped impurities;
wherein the second concentration of P-type doped impurities is sufficient for preventing a leakage current from flowing between the N-type drain and the P-type substrate while the native NMOS device is in operation.

2. The native NMOS device of claim 1, further comprising:
a first pocket region and a second pocket region, both of which are located vertically below the gate and are formed in the P-type epitaxial layer outside the first P-type well and the second P-type well, respectively, by one same ion implantation process step;
wherein each of the first pocket region and the second pocket region has a third concentration of P-type doped impurities, and wherein the third concentration of P-type doped impurities is higher than the first concentration of P-type doped impurities;
wherein the third concentration of P-type doped impurities is sufficient for preventing the leakage current from flowing between the N-type drain and the N-type source while the native NMOS device is OFF.

3. The native NMOS device of claim 1, further comprising:
a first N-type lightly doped drain (LDD) and a second N-type LDD, both of which are located vertically below the gate and are formed in the P-type epitaxial layer outside the N-type source and the N-type drain, respectively, by one same ion implantation process step;
wherein the first N-type LDD and the second N-type LDD are in contact with a lateral side of the N-type source and a lateral side of the N-type drain, respectively, wherein the lateral sides of the N-type source and the N-type drain are in the P-type epitaxial layer which is located vertically below the gate.

4. The native NMOS device of claim 2, further comprising:
a first N-type lightly doped drain (LDD) and a second N-type LDD, both of which are located vertically below the gate and are formed in the P-type epitaxial layer outside the N-type source and the N-type drain, respectively, by one same ion implantation process step;
wherein the first N-type LDD and the second N-type LDD are in contact with a lateral side of the N-type source and a lateral side of the N-type drain, respectively, wherein the lateral sides of the N-type source and the N-type drain are in the P-type epitaxial layer which is located vertically below the gate.

5. The native NMOS device of claim 1, wherein within the operation region, there is no other N-type region in the P-type epitaxial layer, except the N-type source and the N-type drain.

6. The native NMOS device of claim 3, wherein within the operation region, there is no other N-type region in the P-type epitaxial layer, except the N-type source, the N-type drain, the first N-type LDD and the second N-type LDD.

7. The native NMOS device of claim 1, further comprising:
an N-type buried layer, which is formed below and in contact with the P-type epitaxial layer, wherein the N-type buried layer completely encompasses the P-type epitaxial layer within the operation region; and
a first isolation region and a second isolation region, both of which are located on the N-type buried layer and are formed in the P-type epitaxial layer outside the first insulation region and the second insulation region, respectively, by one same ion implantation process step;
wherein both the first isolation region and the second isolation region are not within the operation region.

8. The native NMOS device of claim 7, wherein when the native NMOS device includes the first N-type LDD and the second N-type LDD, within the operation region, there is no other N-type region in the P-type epitaxial layer, except the N-type source, the N-type drain, the first N-type LDD, the second N-type LDD and the N-type buried layer;
wherein when the native NMOS device does not include the first N-type LDD and the second N-type LDD, within the operation region, there is no other N-type region in the P-type epitaxial layer, except the N-type source, the N-type drain and the N-type buried layer.

9. The native NMOS device of claim 1, wherein the P-type epitaxial layer has a volume resistance which is equal to 45 Ohm-cm.

10. A manufacturing method of a native NMOS device, comprising following steps:
forming a P-type epitaxial layer on a P-type substrate, wherein the P-type epitaxial layer has a first concentration of P-type doped impurities;
forming a first insulation region and a second insulation region on the P-type epitaxial layer, wherein the first insulation region and the second insulation region are configured to define an operation region between the first insulation region and the second insulation region;
forming a first P-type well and a second P-type well in the P-type epitaxial layer by one same ion implantation process step;
forming a gate on the P-type epitaxial layer within the operation region; and
forming an N-type source and an N-type drain in the P-type epitaxial layer within the operation region by one same ion implantation process step, wherein the N-type source and the N-type drain are located below and outside two sides of the gate, respectively, wherein the side of the gate which is closer to the N-type source is a source side and the side of the gate which is closer to the N-type drain is a drain side, and wherein the N-type source is located on the first P-type well, and the N-type drain is located on the second P-type well;
wherein the first P-type well completely encompasses and is in contact with a lower surface of the N-type source;
wherein the second P-type well completely encompasses and is in contact with a lower surface of the N-type drain;
wherein each of the first P-type well and the second P-type well has a second concentration of P-type doped impurities, and wherein the second concentration of P-type doped impurities is higher than the first concentration of P-type doped impurities;
wherein the second concentration of P-type doped impurities is sufficient for preventing a leakage current from flowing between the N-type drain and the P-type substrate while the native NMOS device is in operation.

11. The manufacturing method of claim 10, further comprising:
forming a first pocket region and a second pocket region in the P-type epitaxial layer outside the first P-type well and the second P-type well, respectively, by one same ion implantation process step, wherein the first pocket region and the second pocket region are located vertically below the gate;
wherein each of the first pocket region and the second pocket region has a third concentration of P-type doped impurities, and wherein the third concentration of P-type doped impurities is higher than the first concentration of P-type doped impurities;
wherein the third concentration of P-type doped impurities is sufficient for preventing the leakage current from flowing between the N-type drain and the N-type source while the native NMOS device is OFF.

12. The manufacturing method of claim 10, further comprising:
forming a first N-type lightly doped drain (LDD) and a second N-type LDD in the P-type epitaxial layer outside the N-type source and the N-type drain, respectively, by one same ion implantation process step, wherein the first N-type LDD and the second N-type LDD are located vertically below the gate;
wherein the first N-type LDD and the second N-type LDD are in contact with a lateral side of the N-type source and a lateral side of the N-type drain, respectively, wherein the lateral sides of the N-type source and the N-type drain are in the P-type epitaxial layer which is located vertically below the gate.

13. The manufacturing method of claim 11, further comprising:
forming a first N-type lightly doped drain (LDD) and a second N-type LDD in the P-type epitaxial layer outside the N-type source and the N-type drain, respectively, by one same ion implantation process step, wherein the first N-type LDD and the second N-type LDD are located vertically below the gate;
wherein the first N-type LDD and the second N-type LDD are in contact with outside of the N-type source and the N-type drain, respectively, wherein the outsides of the N-type source and the N-type drain are in the P-type epitaxial layer which is located vertically below the gate.

14. The manufacturing method of claim 10, wherein within the operation region, there is no other N-type region in the P-type epitaxial layer, except the N-type source and the N-type drain.

15. The manufacturing method of claim 12, wherein within the operation region, there is no other N-type region in the P-type epitaxial layer, except the N-type source, the N-type drain, the first N-type LDD and the second N-type LDD.

16. The manufacturing method of claim 10, further comprising following steps:
forming an N-type buried layer below the P-type epitaxial layer, wherein the N-type buried layer is in contact with the P-type epitaxial layer, wherein the N-type buried layer completely encompasses the P-type epitaxial layer within the operation region; and
forming a first isolation region and a second isolation region in the P-type epitaxial layer outside the first insulation region and the second insulation region, respectively, by one same ion implantation process step, wherein the first isolation region and the second isolation region are located on the N-type buried layer;
wherein both the first isolation region and the second isolation region are not within the operation region.

17. The manufacturing method of claim 16, wherein when the native NMOS device includes the first N-type LDD and the second N-type LDD, within the operation region, there is no other N-type region in the P-type epitaxial layer, except the N-type source, the N-type drain, the first N-type LDD, the second N-type LDD and the N-type buried layer;
wherein when the native NMOS device does not include the first N-type LDD and the second N-type LDD, within the operation region, there is no other N-type region in the P-type epitaxial layer, except the N-type source, the N-type drain and the N-type buried layer.

18. The manufacturing method of claim 10, wherein the P-type epitaxial layer has a volume resistance which is equal to 45 Ohm-cm.
